(19) United States
(12) Patent Application Publication
(10) Pub. No.: US 2007/0075798 A1
(43) Pub. Date: Apr. 5, 2007

(54) Voltage control oscillator and voltage control oscillator unit

(75) Inventor: Shinji Amano, Ikoma-gun (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/528,472

(22) Filed: Sep. 28, 2006

(30) Foreign Application Priority Data
Sep. 30, 2005 (JP) 2005-289424

(51) Int. Cl. H03B 5/08

(52) U.S. Cl. 331/167

(57) ABSTRACT

A voltage control oscillator that is provided to suitably receive digital broadcasting and is produced at low costs includes: a resonance circuit that includes variable capacitors, each having a capacitance controlling terminal, that are provided parallel to each other and are connected to an inductor, the circuit resonating at a resonant frequency that varies depending upon a sum of (i) an inductance of the inductor and (ii) capacitances of the variable capacitors; and at least one switch to determine what should be connected to at least one of said capacitance controlling terminals.

This Nonprovisional application claims priority under 35 U.S.C. § 119(a) on Patent Application No. 289424/2005 filed in Japan on Sep. 30, 2005, the entire contents of which are hereby incorporated by reference.

### FIELD OF THE INVENTION

The present invention relates to a voltage control oscillator and a voltage control oscillator unit that include a resonance circuit which includes at least two variable capacitors that are provided parallel to each other and are connected to an inductor, which resonance circuit resonates at a resonant frequency that varies depending upon a sum of an inductance of the inductor and capacitances of the variable capacitors.

### BACKGROUND OF THE INVENTION

Generally, there is a demand for a broadcasting-receiving tuner to have a wide frequency range. For example, a satellite broadcasting-receiving tuner has a source frequency of 950 MHz to 2150 MHz, and a direct-conversion type tuner needs to include a local oscillator that oscillates at a frequency that is the same as the source frequency of 950 MHz to 2150 MHz.

In the case where a voltage control oscillator (the voltage control oscillator may also be referred to as a “VCO” hereinafter) that oscillates in such a wide band frequency range necessary for broadcast receiving is installed on an integrated circuit, it is not possible with one VCO to provide a necessary oscillation frequency range. Therefore, a plurality of VCOs of different oscillation frequency ranges are formed on the integrated circuit, in order to cover the necessary frequency range (see Japanese Unexamined Patent Publication No. 2004-120215 (published on Apr. 15, 2004)(Patent Document 1), for example).

FIG. 11(a) is a circuit diagram illustrating a configuration of a conventional voltage control oscillator unit 980. The voltage control oscillator unit 980 uses a plurality of VCOs. FIG. 11(b) is a graph for describing a relationship (f-V characteristic) between (i) a frequency control voltage V_ctrl and (ii) a frequency control voltage V_ctrl of the conventional voltage control oscillator unit 980. FIG. 11(c) is a circuit diagram illustrating a configuration of a conventional VCO 90 that is provided in the conventional voltage control oscillator unit 980.

In reference to FIG. 11(a), the voltage control oscillator unit 980 includes n pieces of VCOs 90-1 to 90-n. The number n of the VCO is decided on the basis of (i) the oscillation frequency range that is necessary and (ii) the oscillation frequency range that is realized by the respective VCOs.

The VCO unit 980 includes a switching unit 981 . From the VCOs 90-1 to 90-n, the switching unit 981 selects a VCO that generates an oscillation frequency signal to be supplied to a mixer 983. The selection is made in accordance with a control signal that is generated according to an external signal by the control circuit 982. An output signal of the VCO may be supplied to the mixer 983 via a buffer circuit; The VCOs 90-1 to 90-n are connected to a PLL 984, and the PLL 984 is locked at a frequency that is in accordance with an external signal.

Generally, the VCOs 90-1 to 90-n shown in FIG. 11(b) are arranged such that the frequency ranges of the respective VCOs 90-1 to 90-n always cover the entire range of necessary frequency without a break, even if there are variations between the integrated circuits. Specifically, the VCOs 90-1 to 90-n are arranged such that there is some degree of overlap between frequency ranges that are covered by adjacent VCOs.

In reference to FIG. 11(c), a VCO 90 has the same configuration as that of the respective VCOs 90-1 to 90-n, and includes two inductors 903 that are connected, parallel to each other, to a power-supply voltage terminal 919. On the opposite side of the power-supply voltage terminal 919, the inductors 903 are respectively connected to variable capacitors 904. The variable capacitors 904 have capacitance controlling terminals, respectively, that are connected to a frequency control voltage input terminal 921 on the opposite side of the inductors 903. The inductors 903 and the variable capacitors 904 constitute a resonance circuit. An oscillation frequency of the resonance circuit is decided by the inverse of the product of (i) an inductance of the inductors 903 and (ii) a total capacitance of the resonance circuit, including the parasitic capacitances and capacitances of the variable capacitors 904.

The VCO 90 includes a pair of transistors 909. Collectors of the respective transistors 909 are connected to the inductors 903 and the variable capacitors 904. The VCO 90 includes a pair of capacitors 915 that separate a DC for the purpose of supplying a base bias to the respective transistors 909 not via the collectors. One end of a resistor 913 is connected to emitters of the respective transistors 909, and the other end of the resistor 913 is connected to a ground 914. A bias circuit 916 for generating a base bias is connected to bases of the respective transistors 909. In FIG. 11(c), the resistor 913 is connected to the pair of transistors 909, but the resistor 913 may be replaced by a constant-current source. Further, although the resonance circuit in FIG. 11(c) is composed of the inductors 903 and the variable capacitors 904, an additional variable capacitor may be connected for the purpose of, for example, fine adjustment of the oscillation frequency.

A plurality of the VCOs 90-1 to 90-n arranged as described above are provided to the voltage control oscillator unit 980, and the VCOs 90-1 to 90-n are arranged such that there is some degree of overlap between frequency ranges that are covered by adjacent VCOs. This makes it possible to cover the wide oscillation frequency range as shown in FIG. 11(b).

However, the above configuration requires many VCOs. This causes an increase in the chip size of the integrated circuit, and therefore a problem arises that the costs increase. The reason therefor is that, especially, an inductor-on-chip occupies a significantly large area due to its configuration, which inductor-on-chip is necessary for realizing a VCO on an integrated circuit. Accordingly, in order to avoid an increase in costs, it is necessary to widen, as wide as possible, a variable range of oscillation frequency of respective VCOs so that the number of VCOs to be provided on the integrated circuit is minimized as few as possible.

On the other hand, in order to receive digital broadcasting a local oscillation signal is necessary that is low in phase noise. If the variable range of oscillation frequency of the respective VCOs is widen, a VCO gain Kv (rate of change in oscillation frequency with respect to control voltage) increases. If the VCO gain Kv increases, a problem arises that the phase noise deteriorates. The reason therefor is that, if the VCO gain Kv increases and a noise is mixed to the control voltage, the rate of change increases in converting the noise into a frequency.

As described above, in order to provide, while keeping the costs low, an integrated circuit with a local oscillator having (i) a wide bandwidth that is sufficient for suitably receiving digital broadcasting and (ii) low phase noise, it is necessary to use a minimum possible number of inductors, while the VCO gain Kv is minimized as low as possible.

### SUMMARY OF THE INVENTION

The present invention is in view of the above problems, and has as an object to provide a voltage control oscillator and a voltage control oscillator unit that are provided to suitably receive digital broadcasting and are produced at low costs.

In order to achieve the above object, a voltage control oscillator of the present invention is adapted so that the voltage control oscillator includes: a resonance circuit including at least two variable capacitors, each having a capacitance controlling terminal, that are provided parallel to each other and are connected to an inductor, the circuit resonating at a resonant frequency that varies depending upon a sum of (i) an inductance of the inductor and (ii) capacitances of the at least two variable capacitors; and at least one switch to determine what should be connected to at least one of the capacitance controlling terminals.

With the above feature, it becomes possible to determine what should be connected to at least one of the capacitance controlling terminals, which variable capacitors are provided parallel to each other and are connected to the inductor. This makes it possible to cover different oscillation frequency ranges depending upon what the capacitance controlling terminal is connected to. As such, it is possible to obtain plural kinds of oscillation-frequency to frequency-control-voltage characteristics, while keeping the VCO gain Kv low. Accordingly, it becomes possible to widen the variable range of oscillation frequency that is covered, while keeping the VCO gain Kv low, so as to reduce the number of inductors to be used. This makes it possible to provide a voltage control oscillator that (i) oscillates at a frequency range with a wide bandwidth that is necessary for satellite-broadcasting receiving (ii) is low in the phase noise, and (iii) is configured on a relatively small area on an integrated circuit. Therefore, a voltage control oscillator is provided that suitably receives satellite digital broadcasting and is produced at low costs.

In order to achieve the above object, a voltage control oscillator unit of the present invention is adapted so that the voltage control oscillator unit includes: a plurality of voltage control oscillators of the present invention; and a switch unit to select and output one of output signals of the plurality of voltage control oscillators.

With the above feature, it becomes possible to provide a plurality of voltage control oscillators of the present invention, which voltage control oscillators have oscillation frequencies that are shifted from each other. This makes it possible to provide a voltage control oscillator unit that covers a wide oscillation frequency range and therefore reduce the number of inductors to be used, while keeping the VCO gain Kv low.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a circuit diagram illustrating a configuration of a voltage control oscillator, according to Embodiment 1 of the present invention.

FIGS. 2(a) and 2(b) are graphs for describing C-V characteristics of the voltage control oscillator. FIG. 2(c) is a graph for describing f-V characteristics of the voltage control oscillator. FIG. 2(d) is a graph for describing C-V characteristics of the voltage control oscillator. Finally, FIG. 2(e) is a graph for describing f-V characteristics of the voltage control oscillator.

FIG. 3 is a circuit diagram illustrating a configuration of a voltage control oscillator of Embodiment 2.

FIG. 4 is a circuit diagram illustrating a configuration of a voltage control oscillator of Embodiment 3.

FIG. 5(a) is a diagram illustrating a configuration of an inductor provided in the voltage control oscillator of Embodiment 3. FIG. 5(b) is a diagram illustrating another configuration of the inductor.

FIG. 6(a) is a circuit diagram illustrating a configuration of a switch provided in the voltage control oscillator of Embodiment 3. FIG. 6(b) is a circuit diagram illustrating another configuration of the switch.

FIG. 7 is a circuit diagram illustrating a configuration of a voltage control oscillator of Embodiment 4.

FIGS. 8(a) and 8(b) are graphs for describing C-V characteristics of the voltage control oscillator. FIG. 8(c) is a graph for describing f-V characteristics of the voltage control oscillator. FIG. 8(d) is a graph for describing C-V characteristics of a voltage control oscillator of Embodiment 5. Finally, FIG. 8(e) is a graph for describing f-V characteristics of the voltage control oscillator.

FIG. 9 is a circuit diagram illustrating a configuration of the voltage control oscillator of Embodiment 5.

FIG. 10(a) is a circuit diagram illustrating a configuration of a voltage control oscillator unit of Embodiment 6. FIG. 10(b) is a graph for describing f-V characteristics of the voltage control oscillator unit.

FIGS. 11(a) to 11(c) illustrate conventional art. Specifically, FIG. 11(a) is a circuit diagram illustrating a configuration of a conventional voltage control oscillator unit. FIG. 11(b) is a graph for describing f-V characteristics of the conventional voltage control oscillator unit. Finally, FIG. 11(c) is a circuit diagram illustrating a configuration of a conventional voltage control oscillator provided in the conventional voltage control oscillator unit.

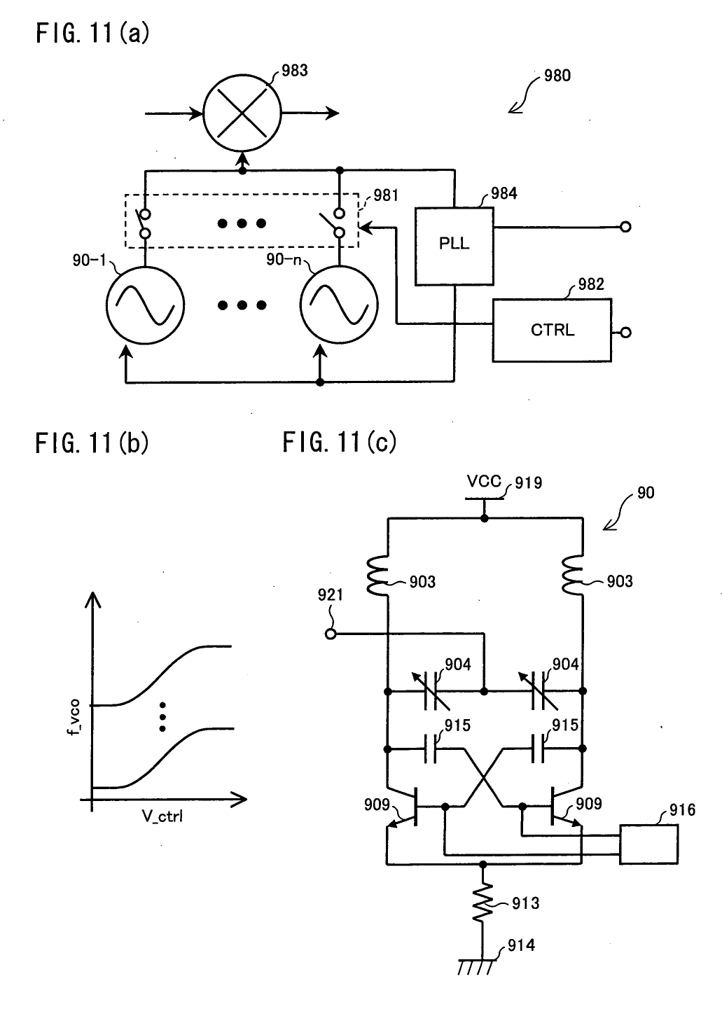

### DESCRIPTION OF THE EMBODIMENTS

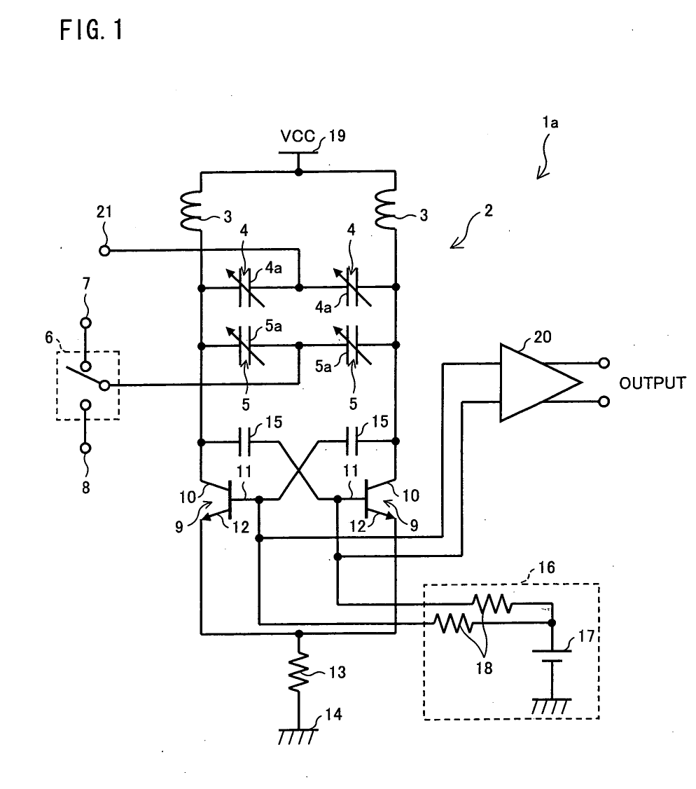

The following describes an embodiment of the present invention, with reference to FIGS. 1 to 10(b).

(Embodiment 1)

FIG. 1 is a circuit diagram illustrating a configuration of a voltage control oscillator la, according to Embodiment 1 of the present invention. The VCO 1a includes two inductors 3 that are connected, parallel to each other, to a power-supply voltage terminal 19. On the opposite side of the power-supply voltage terminal 19, the inductors 3 are respectively connected to variable capacitors 4 power-supply voltage terminal. The variable capacitors 4 have capacitance controlling terminals 4a, respectively, that are connected to a frequency control voltage input terminal 21 on the opposite side of the inductors 3.

Further, on the side of the inductors 3 opposite the power-supply voltage terminal 19, the variable capacitors 4 are connected to variable capacitors 5, respectively. The variable capacitors 5 have capacitance controlling terminals 5a, respectively, that are connected to a switch 6 on the opposite side of the inductors 3. The switch 6 selectively connects the capacitance controlling terminals 5a to any one of (i) a voltage terminal 7 to which a predetermined voltage is supplied and (ii) a voltage terminal 8 to which another predetermined voltage is supplied.

The inductors 3 and the variable capacitors 4 and 5 constitute a resonance circuit 2. An oscillation frequency of the resonance circuit 2 is decided by the inverse of the product of (i) an inductance of the inductors 3 and (ii) a total capacitance of the resonance circuit 2, including the capacitances and parasitic capacitances of the variable capacitors 4 and 5.

The VCO 1a includes a pair of transistors 9. Collectors 10 of the respective transistors 9 are connected to the inductors 3 and the variable capacitors 4 and 5. The VCO 1a also includes a pair of capacitors 15 that separate a DC for the purpose of supplying a base bias voltage to the respective transistors 9 not via the collectors 10. One end of a resistor 13 is connected to emitters 12 of the respective transistors 9, and the other end of the resistor 13 is connected to a ground 14. The resistor 13 may be replaced by a constant-current source. Further, although the resonance circuit 2 in FIG. 1 is composed of the inductors 3 and the variable capacitors 4 and 5, an additional variable capacitor may be connected for the purpose of, for example, fine adjustment of the oscillation frequency. A bias circuit 16 for generating a base bias voltage is connected to bases 11 of the respective transistors 9. The bias circuit 16 is composed of (i) a voltage source 17 and (ii) resistors 18 that are provided between the voltage source 17 and the bases 11 of the respective transistors 9.

An output signal of the VCO 1a is taken out from the bases 11 of the transistors 9 via a buffer 20, for example. Note that it is also possible to take out the output signal from the collectors 10 of the transistors 9 in the same manner, for example.

If a voltage drop of the inductors 3 is small enough to be ignored, a DC voltage that is applied to a terminal of the variable capacitors 4 is a power supply voltage VCC, and a frequency control voltage that is inputted to the frequency control voltage input terminal 21 is applied to the other capacitance controlling terminal 4a. This causes a capacitance of the variable capacitors 4 to be changed in accordance with the frequency control voltage that is inputted to the frequency control voltage input terminal 21. Accordingly, it is possible to control the oscillation frequency of the VCO la illustrated in FIG. 1, by using the frequency control voltage that is inputted to the frequency control voltage input terminal 21.

Further, in FIG. 1, the capacitance controlling terminals 5a of the variable capacitors 5 are connected to the switch 6. The switch 6 selectively connects the capacitance controlling terminals 5a to any one of (i) a voltage terminal 7 to which a predetermined voltage is supplied and (ii) a voltage terminal 8 to which another predetermined voltage is supplied.

The transistors 9 amplify an oscillation signal that is generated in the resonance circuit 2. The collectors 10 of the transistors 9 are connected to the resonance circuit 2, which is constituted by the inductors 3 and the variable capacitors 4 and 5. Between a base 11 and a collector 10 of the other transistor 9, DC is separated by the capacitors 15, while AC is coupled. A DC voltage is supplied to the base 11 from the bias circuit 16, which is provided separately. The emitters 12 of the transistors 9 of a differential-type are connected to each other, and are connected to the ground 14 via the resistor 13.

Although the power-supply voltage of the VCO 1a is used as the power supply voltage VCC in FIG. 1, the power supply voltage VCC does not necessarily have to be a power-supply voltage of the entire integrated circuit in which the VCO la is provided. Further, although a bipolar NPN transistor is used as the transistors 9, the transistors 9 do not have to be an NPN transistor and may be realized by an NMOS transistor. Furthermore, it is possible to realize same characteristics by using a PNP transistor or a PMOS transistor.

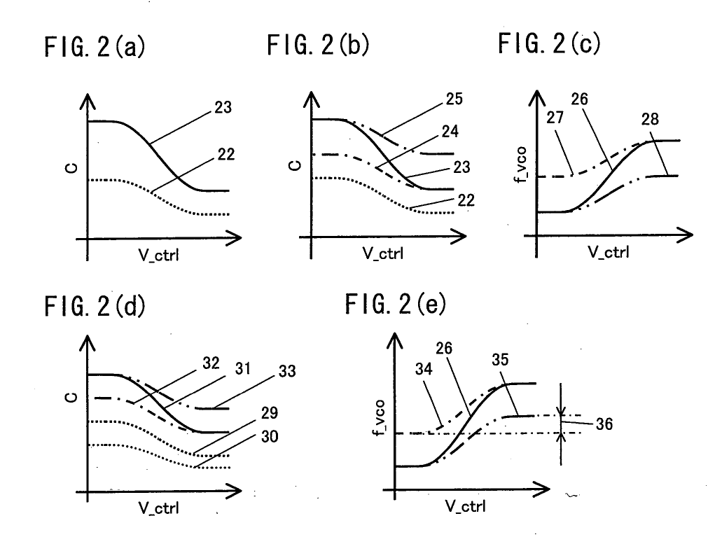

FIGS. 2(a) and 2(b) are graphs for describing C-V characteristics of the voltage control oscillator 1a. FIG. 2(c) is a graph for describing f-V characteristics of the voltage control oscillator 1a. FIG. 2(d) is a graph for describing C-V characteristics of the voltage control oscillator 1a. Finally, FIG. 2(e) is a graph for describing f-V characteristics of the voltage control oscillator 1a.

The following describes how the oscillation frequency of the VCO 1a illustrated in FIG. 1 changes in accordance with (i) a frequency control voltage that is applied to the frequency control voltage input terminal 21 and (ii) a connection state of the switch 4, with reference to FIGS. 2(a) to 2(e). The horizontal axes V_ctrl in FIGS. 2(a) to 2(e) indicate a frequency control voltage that is applied to one end of the variable capacitor 4. The vertical axes C in FIGS. 2(a), 2(b), and 2(d) indicate a capacitance of the variable capacitors. Finally, the vertical axes f_vco in FIGS. 2(c) and 2(e) indicate an oscillation frequency of the VCO 1a.

In FIG. 2(a), a curve 22 shows C-V characteristics of one variable capacitor 5, whereas a curve 23 shows C-V characteristics in the case where two variable capacitors 4 and 5 are connected in parallel. In FIG. 2(b), a curve 24 shows C-V characteristics of the total capacitance in the case where one variable capacitor 5, among two variable capacitors 4 and 5, is fixed at a minimum capacitance. Further, a curve 25 in FIG. 2(b) shows C-V characteristics of the total capacitance in the case where one variable capacitor 5, among two variable capacitors 4 and 5, is fixed at a maximum capacitance. Curves 26, 27, and 28 in FIG. 2(c) show f-V characteristics of the VCO 1a that are based on the C-V characteristics of the curves 23, 24, and 25 in FIG. 2(b), respectively. It can be said from FIG. 2(c) that, by fixing the capacitance of the variable capacitor 5 at the maximum capacitance or the minimum capacitance, two f-V characteristics of the curves 27 and 28 are obtained, which two f-V characteristics (i) are low in a VCO gain Kv and (i) cover the same frequency variable range as the frequency variable range of the f-V characteristics of one curve 26 that are high in the VCO gain Kv. This is realized by the switching performed by the switch 6 in FIG. 1.

Further, in the case where a variable capacitance of the C-V characteristics of the curve 31 is realized by the variable capacitors having the C-V characteristics of the curves 29 and 30 in FIG. 2(d), it is possible to obtain the C-V characteristics of the curve 32 or the curve 33 by varying the capacitance of the variable capacitor of the curve 29 of the wider variable width, with the capacitance of the variable capacitor of the curve 30 of the narrower variable width at the maximum capacitance or minimum capacitance. This makes it possible to obtain an oscillation frequency that has the f-V characteristics of the curves 34 and 35 shown in FIG. 2(e). This ensures that an overlap 36 is provided, so that a continuous oscillation frequency is obtained even if the oscillation frequency fluctuates during mass production.

As the foregoing described, with the VCO 1a arranged as illustrated in FIG. 1, it is possible to obtain plural kinds of f-V characteristics. As such, with the VCO 1a using a set of the inductors, it is possible to cover a wide variable range of oscillation frequency, while keeping the VCO gain Kv low and the phase noise low.

(Embodiment 2)

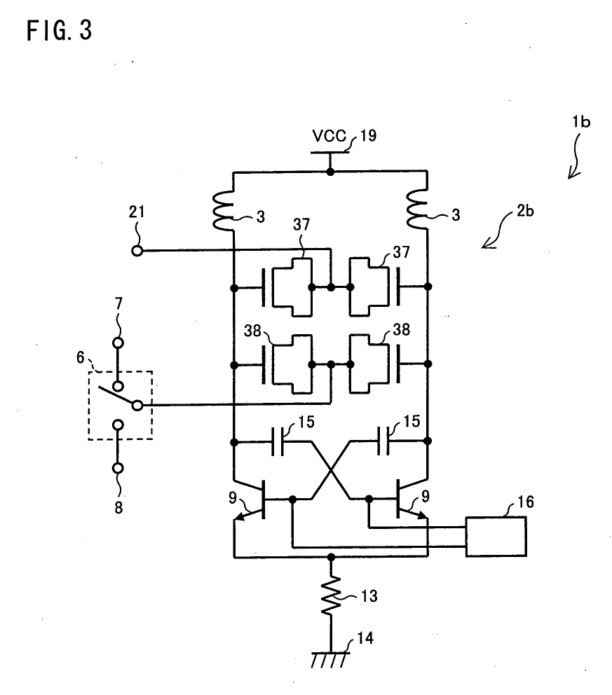

FIG. 3 is a circuit diagram illustrating a configuration of a voltage control oscillator b of Embodiment 2. Components that are the same as the components described above are given the same reference numerals, and detail description thereof is omitted. The same applies to the later shown Figures.

The voltage control oscillator 1b includes MOS-type variable capacitors 37 and 38 in place of the variable capacitors 4 and 5. The greater the variable capacitance ratio of the variable capacitor is, the greater the oscillation-frequency variable-ratio (ratio of oscillation frequency variable width to center frequency) of the VCO 1b will be. The variable capacitance ratio of the variable capacitors is decided by a device that can be used in a process. In the embodiments of the present invention, the VCO gain Kv is suppressed by using variable capacitors whose capacitances are partially fixed. Therefore, the present invention is especially effective if variable capacitors having a large variable capacitance ratio was used. In general, a PN-junction type variable capacitor has a smaller variable capacitance ratio than a MOS-type variable capacitor. Further, in the case of the PN-junction type, it is necessary to separate a DC component by, for example, a capacitor so that the PN junction would not be forward-biased. This causes a further reduction in the effective variable capacitance ratio. Accordingly, if the MOS-type variable capacitors 37 and 38, which have a greater variable capacitance ratio than the PN-junction type variable capacitor, are provided to the voltage control oscillator 1b, it is possible to increase the oscillation-frequency variable-ratio. For this reason, it can be said that the MOS-type variable capacitors are especially suitable variable capacitors for the present invention. With the VCO b illustrated in FIG. 3 that uses the MOS-type variable capacitors 37 and 38 as the variable capacitors, it is possible to realize (i) the f-V characteristics of the curves 27 and 28 shown in FIG. 2(c) and (ii) the f-V characteristics of the curves 34 and 35 shown in FIG. 2(e).

(Embodiment 3)

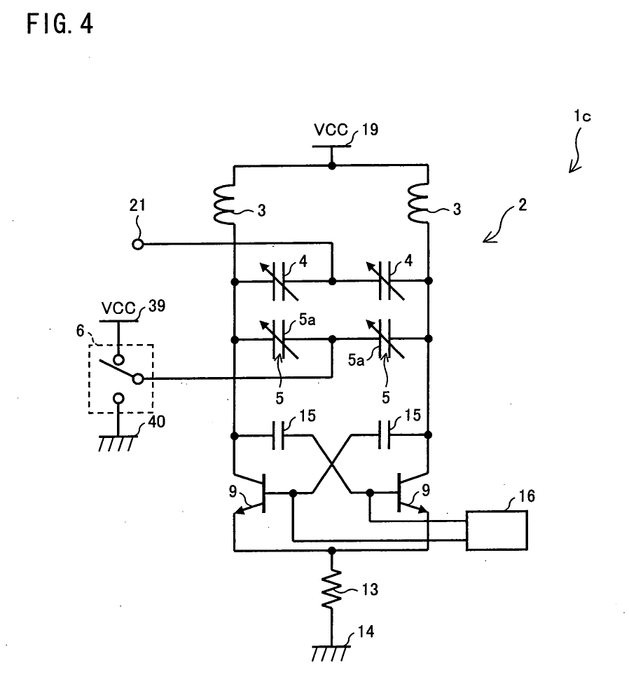

FIG. 4 is a circuit diagram illustrating a configuration of a voltage control oscillator 1c of Embodiment 3. The switch 6 selectively connects the capacitance controlling terminal 5a to any one of (i) a power-supply voltage terminal 39 to which the power-supply voltage VCC is supplied and (ii) a ground 40.

In the case where the C-V characteristics of the variable capacitors in FIG. 2(a) takes (i) a maximum capacitance if the frequency control voltage is 0V and (ii) a minimum capacitance if the frequency control voltage is the power-supply voltage, the capacitance controlling terminals 5a of the variable capacitors 5 are connected to any one of (i) the power-supply voltage terminal 39 and (ii) the ground 40 by the switch 6 such that the switch 6 switches the power-supply voltage terminal 39 and the ground 40, as illustrated in FIG. 4. This makes it possible to realize (i) the f-V characteristics of the curves 27 and 28 shown in FIG. 2(c) and (ii) the f-V characteristics of the curves 34 and 35 shown in FIG. 2(e). Further, if the capacitance controlling terminals of the variable capacitors are arranged such that the capacitance controlling terminals can be connected to the frequency control voltage, the degree of freedom increases significantly in setting the variable range of oscillation frequency and the VCO gain Kv. This makes it possible to use the capacitance controlling terminals with optimum characteristics. This will be described in the Embodiment below.

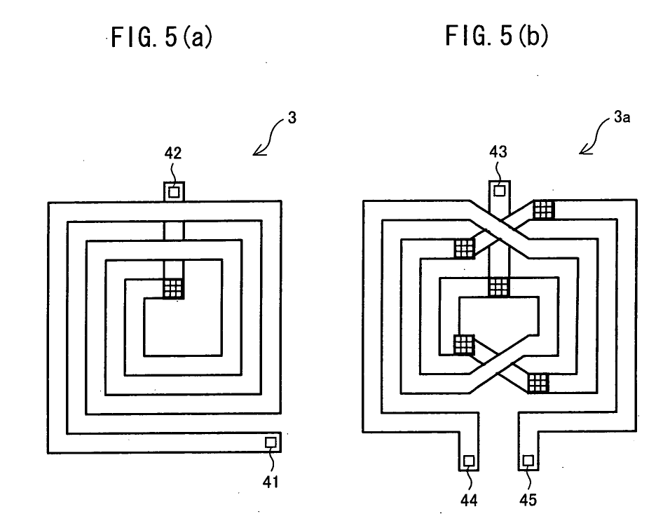

FIG. 5(a) is a diagram illustrating a configuration of an inductor that is provided in the voltage control oscillator 1c of Embodiment 3, and FIG. 5(b) is a diagram illustrating another configuration of the inductor. FIG. 5(a) is an exemplary layout of the inductor 3, whereas FIG. 5(b) is an exemplary layout of a symmetric type inductor 3a. The inductors 3 illustrated in FIGS. 1, 3, and 4 can be configured on an integrated circuit by the layout pattern illustrated in FIG. 5(a). In the case where the inductor 3 having the layout pattern of FIG. 5(a) is used, the terminals 41 and 42 correspond to both ends of the inductor 3. As such, per one VCO circuit, it is necessary to configure two inductors by two inductor cells. Here, the inductor 3a having the layout pattern of FIG. 5(b) is considered. In the case of the inductor 3a having the layout pattern of FIG. 5(b), it is possible to configure the inductors 3 illustrated in FIGS. 1, 3, and 4 by one inductor cell. The reason therefor is that the path from the terminal 44 to the terminal 43 in FIG. 5(b) configures one inductor, and the path from the terminal 45 to the terminal 43 configures the other inductor. The inductor 3a of FIG. 5(b) has the pattern in which two inductors are configured together. This makes it possible to reduce the occupied area on the chip, as compared with the case where two inductors 3 are configured as illustrated in FIG. 5(a).

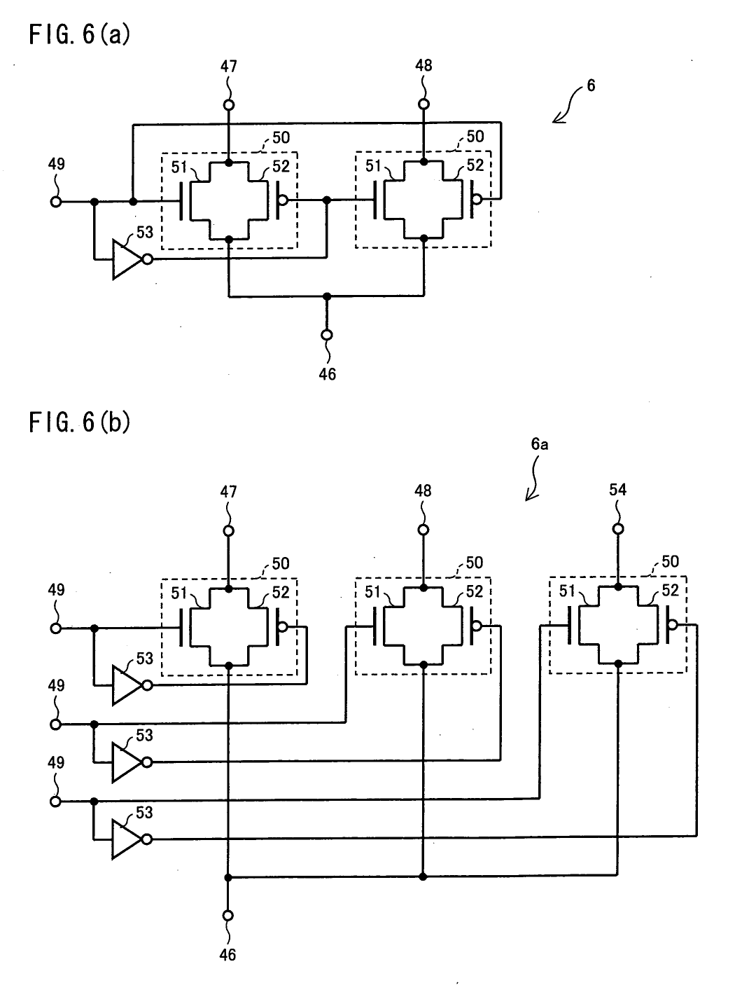

FIG. 6(a) is a circuit diagram illustrating a configuration of a switch that is provided to the voltage control oscillator 1c of Embodiment 3, and FIG. 6(b) is a circuit diagram illustrating another configuration of the switch. The switch 6 in FIG. 6(a) includes a pair of analog switches 50. The respective analog switches 50 are composed of an NMOS transistor 51 and a PMOS transistor 52. Turning on and off the respective analog switches 50 is controlled by (i) a control signal that is inputted to a control signal input terminal 49 and (ii) an inverse control signal of the control signal, which inverse control signal is generated as a result that the inverter 53 reverses the control signal.

In the case of the switch 6 of FIG. 6(a), the analog switches 50 are controlled by the control signal of the signal input terminal 49 such that (i) one of the analog switches 50 is on while the other is off, and (ii) one of the analog switches 50 is off while the other is on. This makes it possible to control, in accordance with the control signal inputted to the control signal input terminal 49, which one of the terminals 47 and 48 the terminal 46 is connected to. In the switch 6 of FIG. 6(a), the terminal 46 is connected to the terminal 47 when the control signal inputted to the control signal input terminal 49 is HIGH, whereas the terminal 46 is connected to the terminal 48 when the control signal is LOW.

Further, with the switch 6a of FIG. 6(b), it is possible to control individually which one of the terminals 47, 48, and 54 the terminal 46 is connected to. The switch 6a of FIG. 6(b) is used in the case where the capacitance controlling terminals of the variable capacitors are connected to a selected one of (i) the power-supply voltage, (ii) the ground, and (iii) the frequency control voltage. This will be described in the embodiment below. In the switch 6a of FIG. 6(b), among the three analog switches 50, an analog switch 50 for which the control signal inputted to the control signal input terminal 49 is HIGH is closed. In view of use in the present invention, because the capacitance controlling terminals of the variable capacitors are connected to the terminal 46, and one of the power-supply voltage, the ground, and the frequency control voltage is connected to the terminals 47, 48, and 54, it is necessary that one of the three control signal input terminals 49 be always HIGH.

(Embodiment 4)

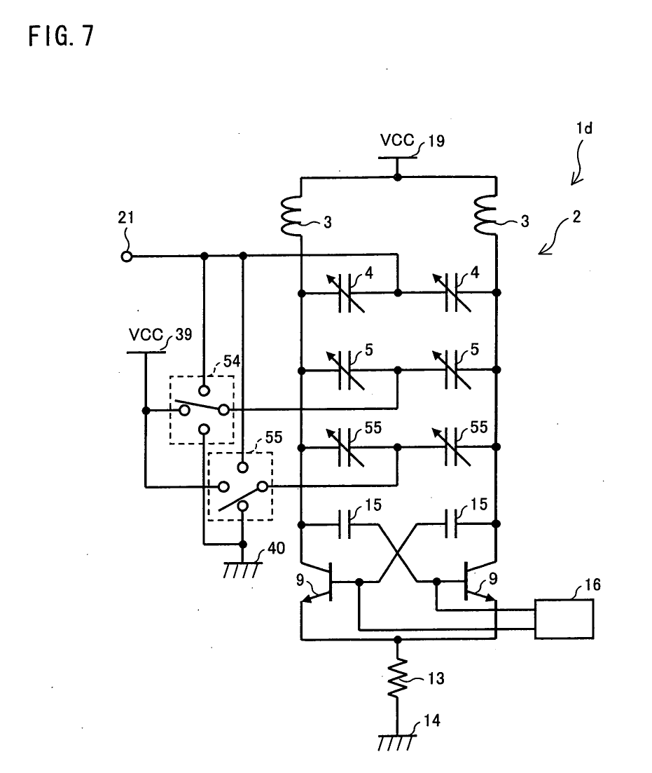

FIG. 7 is a circuit diagram illustrating a configuration of a voltage control oscillator 1d of Embodiment 4. In the VCO 1d of FIG. 7, the variable capacitors 4 are always used as variable capacitances. On the other hand, the capacitance controlling terminals of the variable capacitors 5 and 55 are selectively connected by the switches 54 and 55 to the power-supply voltage terminal 39, the ground 40, or the frequency control voltage input terminal 21.

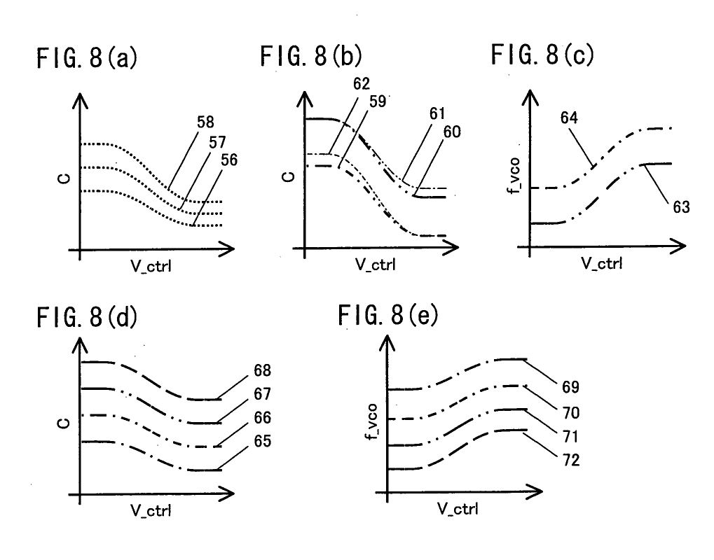

The following describes effects of the present embodiment, with reference to FIGS. 8(a), 8(b), and 8(c). FIGS. 8(a) and 8(b) are graphs for describing the C-V characteristics of the voltage control oscillator 1d, and FIG. 8(c) is a graph for describing the f-V characteristics of the voltage control oscillator 1d.

Here, consideration is made on the C-V characteristics shown in FIG. 8(a) as the C-V characteristics of the variable capacitors. The curve 58 in FIG. 8(a) shows the C-V characteristics of the variable capacitors 4 in FIG. 7. The curve 57 shows the C-V characteristics of the variable capacitors 5. Finally, the curve 56 shows the C-V characteristics of the variable capacitors 55. The variable capacitance of the variable capacitors 5 is greater than the variable capacitance of the variable capacitors 55, and the variable capacitance of the variable capacitors 4 is greater than the variable capacitance of the variable capacitors 5.

In this situation, if the switches 54 and 55 connect the variable capacitors 5 and 55 as shown in Table 1 below, the entire characteristics of the variable capacitors 4, 5, and 55 become (i) the C-V characteristics as shown by the curve 60 in FIG. 8(b) in the case of connection 1 or (ii) the C-V characteristics of the curve 59 in the case of connection 2.

TABLE 1

| VARIABLE | | |
|---|---|---|
| CAPACITANCE | | |
| DEVICE | CONNECTION 1 | CONNECTION 2 |
| 5 | FREQUENCY | VCC |
| | CONTROL | |
| | VOLTAGE | |
| 55 | GROUND | FREQUENCY |
| | | CONTROL |
| | | VOLTAGE |

At this time, the oscillation frequency of the VCO 1d of FIG. 7 changes, as shown in FIG. 8(c), (i) in accordance with the f-V characteristics of the curve 63 in the case of the C-V characteristics of the curve 60 or (ii) in accordance with the f-V characteristics of the curve 64 in the case of the C-V characteristics of the curve 59.

In Table 1, the variable capacitors connected to the ground 40 and the power-supply voltage terminal 39 are changed between connection 1 and connection 2. The following considers the case where the capacitance controlling terminals connected to the ground 40 and the power-supply voltage terminal 39 are not changed. First of all, the case is considered where only the variable capacitors 5 are switched so as to be connected to the ground 40 or the power-supply voltage terminal 39, whereas the variable capacitors 55 are always connected to the frequency control voltage input terminal 21. In this case, the C-V characteristics of the total variable capacitor in a portion that varies depending upon the frequency control voltage are represented by the sum of the curves 58 and 56 in FIG. 8(a). In the case where the capacitance controlling terminals of the variable capacitors 5 are connected to the ground 40, the capacitance when V_ctrl=0 V in the C-V characteristics of the curve 57 is added. In the case where the capacitance controlling terminals of the variable capacitors 5 are connected to the power-supply voltage terminal 39, the capacitance when V_ctrl= power supply voltage VCC is added. In this case, the C-V characteristics of the respective connections are as shown by the C-V characteristics of the respective curves 61 and 59 in FIG. 8(b).

On the other hand, in the case where only the variable capacitors 55 are switched connecting to the ground 40 or to the power-supply voltage terminal 39, whereas the variable capacitors 5 are always connected to the frequency control voltage input terminal 21, the C-V characteristics of a part of the total variable capacitance, which part changes depending upon the frequency control voltage, become the sum of the curves 58 and 57 in FIG. 8(a). The capacitance of the C-V characteristics of the curve 56 is added depending upon how the connection is made. In this case, the C-V characteristics in the cases of the respective connections become the C-V characteristics of the curves 60 and 62 in FIG. 8(b).

In comparison of the above conditions, the slopes of those two C-V characteristics of the curves 60 and 62 in the case where only the variable capacitors 55 are switched are sharper than the slopes of those two C-V characteristics of the curves 61 and 59 in the case where only the variable capacitors 5 are switched. The reason therefor is that, as shown in FIG. 8(a), the slope of the curve 57, which shows the C-V characteristics of the variable capacitors 5 is sharper than the slope of the curve 56, which shows the C-V characteristics of the variable capacitors 55.

In the case where the VCO is composed of variable capacitors that have the same C-V characteristics, the gain Kv of the VCO increases as the oscillation frequency is increased, provided that the variable capacitance ratio remains constant. Further, the phase noise deteriorates as the oscillation frequency is increased. Therefore, if the VCO is arranged such that the variable capacitance ratio is fixed, the phase noise deteriorates in high-frequency oscillation than in low-frequency oscillation. It can be said from the foregoing that the overall characteristics are improved if the variable capacitance ratio is set to increase in low-frequency oscillation, and decrease in high-frequency oscillation. Accordingly, with the present embodiment, it is possible to realize the C-V characteristics of the curves 60 and 59 in FIG. 8(b), while suppressing phase noise low and obtaining the necessary variable range of oscillation frequency.

(Embodiment 5)

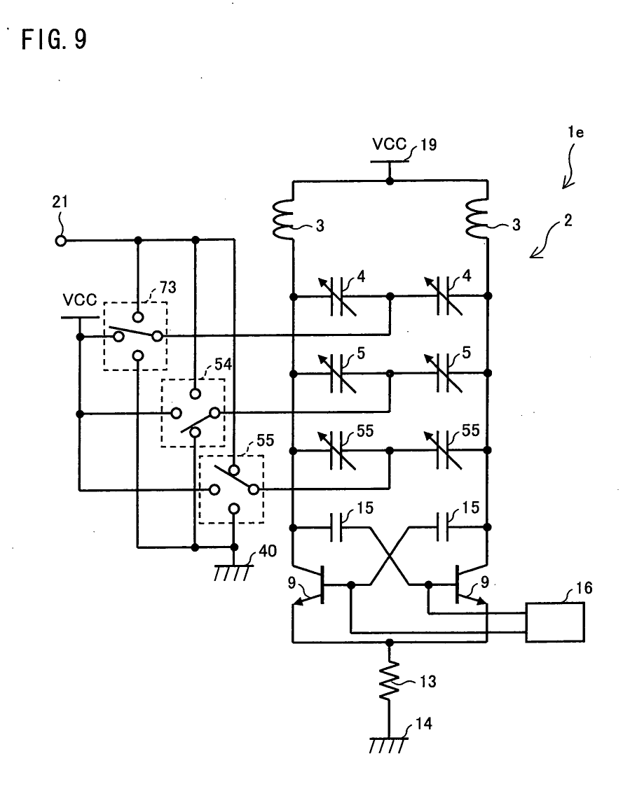

FIG. 9 is a circuit diagram illustrating a configuration of a voltage control oscillator 1e of Embodiment 5. The voltage control oscillator 1e of FIG. 9 further includes a switch 73, in addition to the components mentioned in Embodiment 4. As such, it is possible to selectively connect the capacitance controlling terminals of the variable capacitors 4 to the power-supply voltage terminal 39, the ground 40 or the frequency control voltage terminal 21. If the C-V characteristics of the variable capacitors 4, 5, and 55 in FIG. 9 are the same as the C-V characteristics shown by the curves 58, 57, and 56 in FIG. 8(a), those four C-V characteristics shown in FIG. 8(d) are realized by switching, with the switches 73, 54, and 55, among the connections 1 to 4 as examples in Table 2 below.

TABLE 2

| VARIABLE | | | | |
|---|---|---|---|---|
| CAPACITANCE | CONNECTION | CONNECTION | CONNECTION | CONNECTION |
| DEVICE | 1 | 2 | 3 | 4 |
| 4 | FREQUENCY | FREQUENCY | VCC | VCC |
| | CONTROL | CONTROL | | |
| | VOLTAGE | TERMINAL | | |
| 5 | GROUND | GROUND | FREQUENCY | FREQUENCY |
| | | | CONTROL | CONTROL |
| | | | TERMINAL | TERMINAL |
| 55 | GROUND | VCC | GROUND | VCC |

The overall C-V characteristics of the variable capacitors 4, 5, and 55 are shown by (a) the curve 65 in FIG. 8(d) in the case of connection 1 in Table 2, (b) the curve 66 in the case of connection 2, (c) the curve 67 in the case of connection 3, and (d) the curve 68 in the case of connection 4. At this time, the f-V characteristics of the VCO 1e in FIG. 9 become those as shown in FIG. 8(e). Specifically, the C-V characteristics of the curve 65 correspond to the f-V characteristics of the curve 69. The C-V characteristics of the curve 66 correspond to the f-V characteristics of the curve 70. The C-V characteristics of the curve 67 correspond to the f-V characteristics of the curve 71. Finally, the C-V characteristics of the curve 68 correspond to the f-V characteristics of the curve 72. Concerning the slopes of the C-V characteristics and the variable widths in the same manner as in Embodiment 4, the greater the oscillation frequency is, the smaller the variable capacitance ratio and the frequency variable ratio are suppressed in Embodiment 5. Furthermore, the slopes of the respective f-V characteristics shown in FIG. 8(e) are even smaller than those in FIG. 8(c), which show the case of Embodiment 4. Accordingly, with the present embodiment, a VCO is provided that the VCO gain Kv and the phase noise are suppressed further low.

(Embodiment 6)

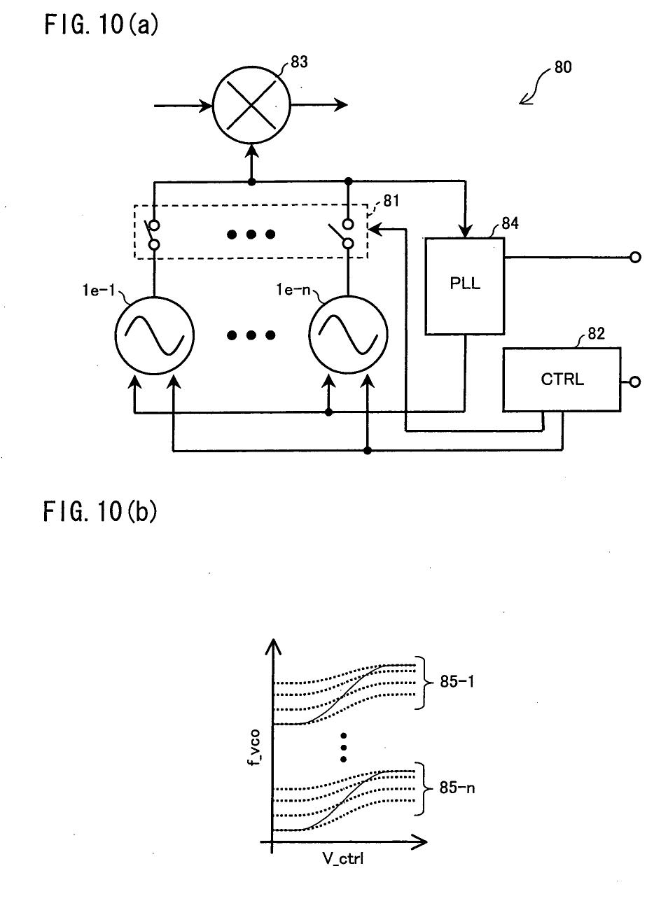

FIG. 10(a) is a circuit diagram illustrating a configuration of a voltage control oscillator unit 80 of Embodiment 6, and FIG. 10(b) is a graph for describing f-V characteristics of the voltage control oscillator unit 80. The voltage control oscillator unit 80 includes n pieces of VCOs 1e-1 to 1e-n. The respective VCOs 1e-1 to 1e-n have the same configuration as the VCO 1e described in Embodiment 5, which VCO 1e can set the f-V characteristics as shown in FIG. 8(e) by switching the connection of the capacitance controlling terminals of the variable capacitors. The number n of the VCO is decided on the basis of (i) the oscillation frequency range that is necessary and (ii) the oscillation frequency ranges that are realized by the respective VCOs.

The VCO unit 80 includes a switch unit 81. The switch unit 81 selects, in accordance with a control signal that is generated by a control circuit 82 as set forth in an external signal, a VCO that supplies an oscillation frequency signal to the mixer 83, from the VCOs 1e-1 to 1e-n. Another way is that an output signal of the VCO is supplied to the mixer 83 via a buffer circuit. The control circuit 82 decides the f-V characteristics of the respective VCOs. The VCOs 1e-1 to 1e-n are connected to a PLL 84, and the PLL 84 locks a frequency of the oscillation frequency signal of the VCOs 1e-1 to 1e-n at a frequency of a signal supplied to the PLL 84 from the outside.

FIG. 10(b) illustrates a relationship between (i) a frequency control voltage provided to the respective VCOs that are configured as illustrated in FIG. 10(a) and (ii) an oscillation frequency of the respective VCOs. Because the respective VCOs 1e-1 to 1e-n have the configuration of Embodiment 5 of the present invention, the f-V characteristics 85-1 to 85-n are shown by a plurality of f-V characteristics, as shown in FIG. 10(b). The VCOs 1e-1 to 1e-n are configured as illustrated in FIG. 10(a) so that the f-V characteristics 85-1 to 85-n shown in FIG. 10(b) are obtained. As such, a VCO unit that covers a wide oscillation frequency range while keeping the phase noise low.

Further, a plurality of VCOs may be arranged such that a VCO with a higher oscillation frequency has a smaller oscillation-frequency variable-ratio. By this way, a VCO unit is provided that is low in the phase noise.

Further, operations of a VCO, among the plurality of VCOs, that is not selected by the control circuit 82 may be stopped. By this way, consumption of current is reduced, and therefore low power-consumption is achieved.

The present invention is not limited to the description of the embodiments above, but may be altered by a skilled person within the scope of the claims. An embodiment based on a proper combination of technical means disclosed in different embodiments is encompassed in the technical scope of the present invention.

The present invention is applicable to an integrated circuit including a voltage control oscillator or a voltage control oscillator unit that oscillates in a continuous wide frequency range. The present invention is also applicable to a receiving device using the integrated circuit, especially a receiving device that is used as a broadcasting receiver such as a satellite broadcasting receiver.

It is preferable in the voltage control oscillator of the present embodiment that each of the at least two variable capacitors be a MOS-type variable capacitor.

The above configuration is preferable because a MOS-type variable capacitor is greater in a variable capacitance ratio than a PN-junction type variable capacitor, and the greater the variable capacitance ratio is, the greater the oscillation-frequency variable-ratio (ratio of oscillation frequency variable width to center frequency) of the VCO becomes.

It is preferable in the voltage control oscillator of the present embodiment that the at least one switch connects the at least one of the capacitance controlling terminals to a frequency control voltage input terminal, a power supply, or a ground.

With the above configuration, it becomes possible to cover different oscillation frequency ranges depending upon which one of (i) the frequency control voltage input terminal, (ii) the power supply, and (iii) the ground the capacitance controlling terminal is connected to. As such, it is possible to obtain plural kinds of characteristics of oscillation-frequency to frequency-control-voltage, while keeping the VCO gain Kv low.

It is preferable in the voltage control oscillator of the present embodiment that the resonance circuit be a differential-type resonance circuit, and the inductor include at least one inductor element.

In the above configuration, the resonance circuit is a differential type, and therefore a frequency signal that is oscillated is stably supplied.

It is preferable in the voltage control oscillator of the present embodiment that the inductor be a single symmetric-type inductor.

With the above configuration, it becomes possible to configure two inductors in a form of one inductor cell on the integrated circuit. Therefore, the inductor occupies a smaller area on the integrated circuit than in the case where the two inductors are configured in a form of two inductor cells.

It is preferable in the voltage control oscillator of the present embodiment that the at least one switch be composed of MOS-type FETs.

With the above configuration, it becomes possible to easily configure a switch that occupies a smaller area by using an NMOSFET or a PMOSFET, in the case where the switch is configured by a BiCMOS process, a CMOS process, or the like.

It is preferable that the number of the at least one switch be one.

With the above configuration, it becomes possible with a simple configuration to widen the oscillation frequency range of the voltage control oscillator, while keeping the VCO gain Kv low.

It is preferable in the voltage control oscillator of the present embodiment that: the at least one switch include two switches; one of the two switches determine what should be connected to a capacitance controlling terminal of one of the at least two variable capacitors; and another one of the two switches determines what should be connected to a capacitance controlling terminal of another one of the at least two variable capacitors.

With the above configuration, it becomes possible to further widen the oscillation frequency range, while keeping the VCO gain Kv low.

It is preferable in the voltage control oscillator of the present embodiment that: the at least one switch includes three switches; the at least two variable capacitors include three or more variable capacitors; one of the three switches determines what should be connected to a capacitance controlling terminal of one of the three more variable capacitors; another one of the three switches determines what should be connected to a capacitance controlling terminal of another one of the three or more variable capacitors; and a further one of the three switches determines what should be connected to a capacitance controlling terminal of a further one of the three or more variable capacitors.

With the above configuration, it becomes possible to further widen the oscillation frequency range of the voltage control oscillator, while keeping the VCO gain Kv lower.

It is preferable in the voltage control oscillator unit of the present embodiment that, in the plurality of voltage control oscillators, the higher an oscillation frequency is, the smaller an oscillation-frequency variable-ratio is.

With the above feature, it becomes possible to further reduce the VCO gain Kv, and therefore provide a voltage control oscillator unit that is low in the phase noise.

It is preferable that the voltage control oscillator unit of the present embodiment further include a control circuit to control the selecting of the switch unit, the control circuit stopping an operation of a voltage control oscillator whose output signal is not selected by the switch unit.

With this feature, it becomes possible to reduce power consumption of the voltage control oscillator unit.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A voltage control oscillator, comprising:
a resonance circuit including at least two variable capacitors, each having a capacitance controlling terminal, that are provided parallel to each other and are connected to an inductor, said circuit resonating at a resonant frequency that varies depending upon a sum of (i) an inductance of the inductor and (ii) capacitances of the at least two variable capacitors; and
at least one switch to determine what should be connected to at least one of said capacitance controlling terminals.

2. The voltage control oscillator as set forth in claim 1, wherein each of the at least two variable capacitors is a MOS-type variable capacitor.

3. The voltage control oscillator as set forth in claim 1, wherein said at least one switch connects said at least one of said capacitance controlling terminals to a frequency control voltage input terminal, a power supply, or a ground.

4. The voltage control oscillator as set forth in claim 1, wherein the resonance circuit is a differential-type resonance circuit, and the inductor includes at least one inductor element.

5. The voltage control oscillator as set forth in claim 1, wherein the inductor is a single symmetric-type inductor.

6. The voltage control oscillator as set forth in claim 1, wherein said at least one switch is composed of MOS-type FETs.

7. The voltage control oscillator as set forth in claim 1, wherein the number of the at least one switch is one.

8. The voltage control oscillator as set forth in claim 1, wherein:
said at least one switch includes two switches;
one of the two switches determines what should be connected to a capacitance controlling terminal of one of said at least two variable capacitors; and
another one of the two switches determines what should be connected to a capacitance controlling terminal of another one of said at least two variable capacitors.

9. The voltage control oscillator as set forth in claim 1, wherein:
said at least one switch includes three switches;
said at least two variable capacitors include three or more variable capacitors;
one of the three switches determines what should be connected to a capacitance controlling terminal of one of said three or more variable capacitors;
another one of the three switches determines what should be connected to a capacitance controlling terminal of another one of said three or more variable capacitors; and
a further one of the three switches determines what should be connected to a capacitance controlling terminal of a further one of said three or more variable capacitors.

10. A voltage control oscillator unit, comprising:
a plurality of voltage control oscillators set forth in claim 1; and
a switch unit to select and output one of output signals of the plurality of voltage control oscillators.

11. The voltage control oscillator unit as set forth in claim 10, wherein, in the plurality of voltage control oscillators, the higher an oscillation frequency is, the smaller an oscillation-frequency variable-ratio is.

12. The voltage control oscillator unit as set forth in claim 10, further comprising a control circuit to control the selecting of the switch unit,
the control circuit stopping an operation of a voltage control oscillator whose output signal is not selected by the switch unit.
